(19) United States
(12) Patent Application Publication
(10) Pub. No.: US 2010/0188168 A1
(43) Pub. Date: Jul. 29, 2010

(54) WIDE BAND FILTER STRUCTURE

(76) Inventors: Ding-Bing LIN, Yonghe City (TW); Kuo-Chiang HUNG, Pingjhen City (TW)

Correspondence Address: Muncy, Geissler, Olds & Lowe, PLLC, 4000 Legato Road, Suite 310, FAIRFAX, VA, 22033, US

(21) Appl. No.: 12/360,282

(22) Filed: Jan. 27, 2009

(51) Int. Cl. H03H 7/01

(52) U.S. Cl. 333/170; 333/185

(57) ABSTRACT

Provided is a wide band filter structure including two coupling units and one bridge unit. Each of the coupling units has a joint. The joint is concentrically encircled by a spiral with two ends. One of the ends of the spiral is positioned at the joint. The bridge unit is connected to between the two spirals by the other ends thereof, respectively. The wide band filter structure achieves high impedance, prevents wide band Delta-I noise, improves electromagnetic interference (EMI) and electromagnetic compatibility (EMC), and reduces cost when used in related layout of printed circuit boards and IC package substrates.

### BACKGROUND OF THE INVENTION

1. Field of the Invention

The present invention relates to wide band filter structures and, more particularly, to a wide band filter structure including two spiral structures and a bridge structure connected to therebetween.

2. Description of the Prior Art

When it comes to a high-speed logic circuit system, switching a element's signal between states swiftly can generate transient current. The transient current travels between a power plane and a ground plane via a plurality of pins of the element. Excessive variation in the transient current causes great disturbance to voltage between the power plane and the ground plane, contributes to high-frequency harmonic oscillation of the system, and reduces power integrity (PI) of the system. The phenomenon, instability arising from variation in the transient current, is known as delta-I noise. To apply sufficient driving voltage to various logic elements, it is necessary to cut and divide the power plane or the ground plane of a circuit system into fragments or put identical voltage driving elements in a definite region. However, operation of the driving elements entails rapid recharging and discharging between the power plane and the ground plane of the circuit system. The recharging and discharging current crosses the power plane and the ground plane to interfere with the operation of adjacent elements, causing problems of power integrity (PI), electromagnetic interference (EMI), and electromagnetic compatibility (EMC) of the circuit system.

Referring to FIG. 1 and FIG. 2, to minimize the effect of delta-I noise produced by switching an element's signal on operation of other elements and prevent wide band system noise, it is most common to prevent wide band delta-I noise by means of (as shown in FIG. 1 and FIG. 2) a circuit substrate 4 formed with a slot 40 for isolation of first and second elements 41, 42 susceptible to interference from noise and provided with a ferrite bead 5 of high resistance and two 0.1 μF decoupling capacitors 6, 6a.

Improvement in power integrity of a system often requires passive elements, such as the ferrite bead 5, for isolation of a power source to an important circuit (for example, the power plane for PLL or analog circuits) so as to minimize the effect of wide band delta-I noise. Normally, power integrity (PI) and electromagnetic interference (EMI) are improved by the ferrite bead 5 made of a material of high magnetic conductivity. The ferrite bead 5 made of a material of high magnetic conductivity is expensive, and in consequence a circuit system using the ferrite bead 5 incurs design costs. Also, additional costs are incurred in using more said ferrite beads 5, as the number of external I/O ports is increased to meet an increasingly great demand for multiple functions of a single system. Furthermore, connecting the ferrite bead 5 with the two decoupling capacitors 6, 6a in parallel results in intricate architecture and design. Hence, conventional said ferrite beads 5 do not meet needs in practice.

### SUMMARY OF THE INVENTION

In view of this, it is a primary objective of the present invention to provide a wide band filter structure which achieves high impedance, prevents wide band Delta-I noise, improves electromagnetic interference (EMI) and electromagnetic compatibility (EMC), and reduces cost when used in related layout of printed circuit boards and IC package substrates.

To achieve the above and other objectives, the present invention provides a wide band filter structure comprising two coupling units and a bridge unit. Each of the coupling units has a joint. The joint is concentrically encircled by a spiral with two ends. One of the ends of the two spirals is positioned at the joint. The bridge unit is provided between the two coupling units. Two ends of the bridge unit are connected to the two spirals by the other ends thereof, respectively.

### BRIEF DESCRIPTION OF THE DRAWINGS

FIG. 1 is a schematic view of the use of a conventional ferrite bead;

FIG. 2 is an equivalent circuit of FIG. 1;

FIG. 3 is a schematic view of the basic structure of a first preferred embodiment of the present invention;

FIG. 4 is a side elevational view of the use of the first preferred embodiment of the present invention;

FIG. 5 is a top plan view of the use of the first preferred embodiment of the present invention; and

FIG. 6 is a schematic view of the basic structure of a second preferred embodiment of the present invention.

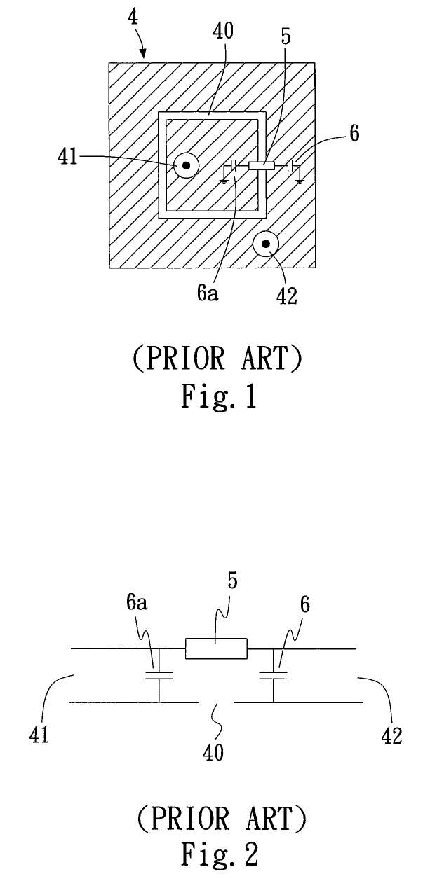

### DETAILED DESCRIPTION OF THE EMBODIMENTS

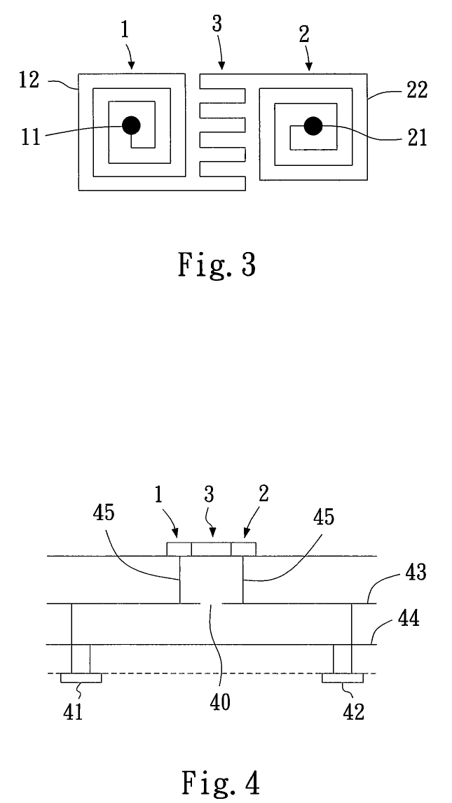

Referring to FIG. 3, which is a schematic view of the basic structure of a first preferred embodiment of the present invention, a wide band filter structure comprises at least two coupling units 1, 2 and a bridge unit 3.

The coupling units 1, 2 are positioned side by side. Each of the coupling units 1, 2 has a joint 11, 21. The joint 11, 21 is concentrically encircled by a spiral 12, 22 with two ends. One of the ends of the spiral 12, 22 is positioned at the joint 11, 21, respectively.

The bridge unit 3 is provided between the two coupling units 1, 2. The bridge unit 3 and the coupling units 1, 2 are coplanar. Two ends of the bridge unit 3 are connected to the other ends of two said spirals 12, 22, respectively. The bridge unit 3 is sideward zigzag-shaped. Upon completion of the above architecture, the wide band filter structure is finalized.

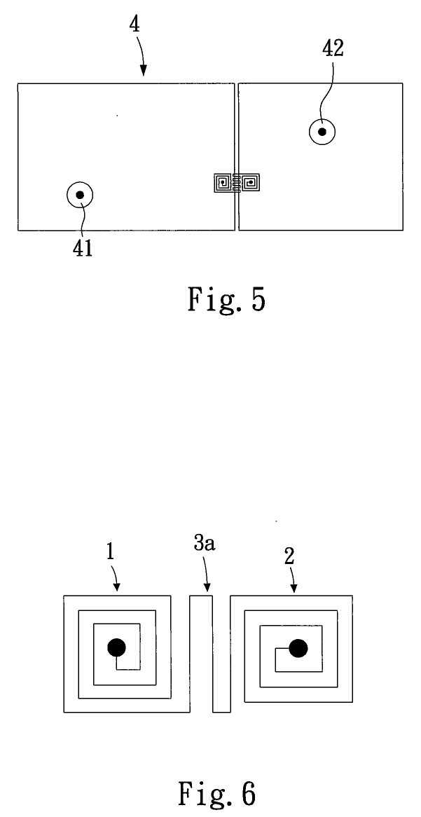

Referring to FIG. 4 and FIG. 5, which are a side elevational view and a top plan view of the use of the first preferred embodiment of the present invention, respectively, the first preferred embodiment of the present invention is characterized in that: a substrate 4 for a printed circuit board is formed by copper etching; isolation of a first element 41 and a second element 42 on the substrate 4 is implemented by etching a slot 40 on a power plane 43 (or ground plane); the joints 11, 21 of the coupling units 1, 2 are straddlingly connected to two ends of the slot 40 via a plurality of vias 45, so as to maintain identical DC level of two said power planes 43 (or ground planes), achieve high impedance between two said power planes (or ground planes), prevent wide band Delta-I noise, and improve electromagnetic interference (EMI) and electromagnetic compatibility (EMC). Alternatively, the first preferred embodiment of the present invention involves applying semiconductor (such as silicon) fabrication process technology to an IC package so as to achieve high impedance. Hence, the present invention has at least the following advantages:

1. Unlike the prior art which disclosed a ferrite bead, the present invention is implemented by a process of layout of a printed circuit board and an IC package substrate as well as a relatively small number of decoupling capacitors, so as to prevent wide band Delta-I noise, improve electromagnetic interference (EMI) and electromagnetic compatibility (EMC), greatly reduce production costs, and enhance accuracy of product design.

2. The present invention is implemented only by circuit layout technology. On the whole, the circuit of the present invention is slightly linear, except the connection between the vias 45 and the power planes 43 (or ground planes). Any existing semiconductor fabrication process can be applied to the IC package. Accordingly, compared to the prior art that disclosed a ferrite bead, the present invention is widely applicable to various products without undergoing any special process.

3. The structure of the present invention has the same dimensions as the ferrite bead 1206 actually used in a circuit, that is, 5.33×2.28 mm². Hence, the structure of the present invention does not increase layout area, and yet with spiral circuit layout being used in the spirals 12, 22 of the coupling units 1, 2, the line width and pitch of the spirals 12, 22 are achieved by the finest circuit process. Furthermore, it is feasible to provide the maximum resistance for layout of the least area, by connecting spiral circuits formed with two adjacent said spirals 12, 22 through the zigzag bridge unit 3.

Referring to FIG. 6, which is a schematic view of the basic structure of a second preferred embodiment of the present invention, in addition to the structure disclosed in the first preferred embodiment, the present invention enables related structural variation in the first preferred embodiment in practice. For instance, the bridge unit 3a can be vertical zigzag-shaped and still achieves all the effects disclosed in the first preferred embodiment and meets practical needs to a greater extent.

In conclusion, the present invention provides a wide band filter structure to eliminate the drawbacks of the prior art. For instance, the wide band filter achieves high impedance, prevents wide band Delta-I noise, effectively improves electromagnetic interference (EMI) and electromagnetic compatibility (EMC), and reduces cost when used in related layout of printed circuit boards and IC package substrates. Hence, the present invention involves an inventive step, demonstrates industrial applicability, meets user needs, and, most importantly, complies with requirements for filing an invention patent application. Accordingly, a patent application is hereby filed.

The foregoing preferred embodiments are only illustrative of the features and functions of the present invention but are not intended to restrict the scope of the present invention. It will be understood by persons skilled in the art that various changes and modifications according to the claims and specification may be effected in the scope of the present invention.

What is claimed is:

1. A wide band filter structure, comprising:
two coupling units each having a joint concentrically encircled by a spiral with two ends, wherein one of the ends of the spiral is positioned at the joint; and
a bridge unit provided between the two coupling units, wherein two ends of the bridge unit are connected to the other ends of two said spirals, respectively.

2. The wide band filter structure of claim 1, wherein the two coupling units and the bridge unit are coplanar.

3. The wide band filter structure of claim 1, wherein the bridge unit is sideward zigzag-shaped.

4. The wide band filter structure of claim 1, wherein the bridge unit is vertical zigzag-shaped.
